(19) United States
(12) Patent Application Publication
(10) Pub. No.: US 2022/0415793 A1
(43) Pub. Date: Dec. 29, 2022

(54) SEMICONDUCTOR MEMORY DEVICE

(71) Applicant: Samsung Electronics Co., Ltd., Suwon-si (KR)

(72) Inventors: Sung Hwan KIM, Yeongcheon-si (KR); Won Ki ROH, Yongin-si (KR); Na Rae JEONG, Osan-si (KR); Seung Uk HAN, Suwon-si (KR)

(21) Appl. No.: 17/696,336

(22) Filed: Mar. 16, 2022

(30) Foreign Application Priority Data
Jun. 28, 2021 (KR) 10-2021-0083756

(51) Int. Cl. H01L 23/528; H01L 27/108; G11C 5/06; H01L 23/522

(52) U.S. Cl. CPC H01L 23/5283; H01L 27/10814; H01L 27/10823; G11C 5/063; H01L 23/5226

(57) ABSTRACT

A semiconductor memory device includes a substrate extending in a first direction and second direction perpendicular to the first direction, bitline structures arranged on a substrate in the first direction, the bitline structures extending in the second direction, spacer structures disposed on sidewalls of the bitline structures to extend in the second direction, the spacer structures including spacers, which are formed of air or silicon oxide, contact structures disposed between the spacer structures and arranged in the second direction; fence structures filling gaps between the contact structures and between the spacer structures, and pad isolation films isolating the contact structures on the bitline structures, the spacer structures, and the fence structures. The fence structures include first fence liners and second fence liners, which are on the first fence liners and are formed of one of air and silicon oxide, and which overlap with the spacers in the first direction.

### CROSS-REFERENCE TO RELATED APPLICATION

This application claims priority to Korean Patent Application No. 10-2021-0083756, filed on Jun. 28, 2021, and all the benefits accruing therefrom under 35 U.S.C. § 119, the disclosure of which is incorporated herein by reference in its entirety.

### BACKGROUND

### 1. Field

The present disclosure relates to a semiconductor memory device.

### 2. Description of the Related Art

As semiconductor devices have become highly integrated, individual circuit patterns for realizing as many semiconductor devices as possible in each given area have increasingly become sophisticated. That is, as the integration density of semiconductor devices has increased, the design rule for the elements and parts of each semiconductor device has decreased.

Thus, it has increasingly become complicated and difficult to form a plurality of wiring lines and a plurality of buried contacts in a highly-scaled semiconductor device.

### SUMMARY

Embodiments of the present disclosure provide a semiconductor memory device with an improved product reliability.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

According to an embodiment of the present disclosure, a semiconductor memory device includes a substrate extending in a first direction and second direction perpendicular to the first direction; bitline structures arranged on the substrate in the first direction, the bitline structures extending in the second direction; spacer structures disposed on sidewalls of the bitline structures to extend in the second direction, the spacer structures including spacers, which are formed of air or silicon oxide; contact structures disposed between the spacer structures and arranged in the second direction; fence structures filling gaps between the contact structures and between the spacer structures; and pad isolation films isolating the contact structures on the bitline structures, the spacer structures, and the fence structures, wherein the fence structures include first fence liners and second fence liners, which are on the first fence liners and are formed of one of air and silicon oxide, and the second fence liners overlap with the spacers in the first direction.

According to the aforementioned and other embodiments of the present disclosure, a semiconductor memory device includes a substrate extending in a first direction and second direction perpendicular to the first direction; bitline structures arranged on a substrate in the first direction, the bitline structures extending in the second direction contact structures disposed between the spacer structures and arranged in the second direction; fence structures filling gaps between the contact structures and between the spacer structures; and pad isolation films isolating the contact structures on the bitline structures, the spacer structures, and the fence structures, wherein the fence structures include first fence liners, which extend along sidewalls of the spacer structures and sidewalls of the contact structures, and second fence liners, which are on the first fence liners, are formed of air, and fill gaps between the contact structures and gaps between the spacer structures, and top surfaces of the second fence liners are defined by the pad isolation films.

According to the aforementioned and other embodiments of the present disclosure, a semiconductor memory device includes a substrate extending in a first direction and second direction perpendicular to the first direction; gate structures including gate electrodes, which extend in the first direction in the substrate, and gate capping films, which extend in the first direction in the substrate; bitline structures extending in the second direction, on the substrate, the bitline structures being arranged in the second direction; spacer structures disposed on sidewalls of the bitline structures to extend in the second direction, the spacer structures including air spacers; contact structures including buried contacts, which are connected to the substrate, between the spacer structures, and are arranged in the second direction, landing pads, which are on the buried contacts, and barrier films, which are disposed between the buried contacts and the landing pads and extend along top surfaces of the buried contacts, sidewalls of the spacer structures, and top surfaces of the bitline structures; fence structures having bottom surfaces defined by the gate capping films, the fence structures filling trenches, which have sidewalls defined by the contact structures and the spacer structures; and pad isolation films isolating the contact structures on the bitline structures, the spacer structures, and the fence structures, wherein top surfaces of the air spacers are defined by the pad isolation films, on the gate structures, the fence structures include first fence liners, which are formed along sidewalls and bottoms of the trenches, and second fence liners, which are formed of air and are defined by the first fence liners and the pad isolation films, and the second fence liners overlap with the spacers in the first direction.

Other features and embodiments may be apparent from the following detailed description, the drawings, and the claims.

### BRIEF DESCRIPTION OF THE DRAWINGS

The above and other embodiments and features of the present disclosure will become more apparent by describing in detail embodiments thereof with reference to the attached drawings, in which:

FIG. 1 is a layout view of a semiconductor memory device according to some embodiments of the present disclosure;

FIG. 2 is a layout view illustrating bitlines, air spacers, buried contacts, landing pads, and fence structures of FIG. 1;

FIG. 3A is a cross-sectional view taken along line A-A of FIGS. 1 and 2;

FIG. 3B is a cross-sectional view taken along line B-B of FIGS. 1 and 2;

FIG. 3C is a cross-sectional view taken along line C-C of FIGS. 1 and 2;

FIG. 3D is a cross-sectional view taken along line D-D of FIG. 3C;

FIGS. 4 and 5 are enlarged cross-sectional views of an area R of FIG. 3B;

FIGS. 6 and 7 are cross-sectional views of a semiconductor memory device according to some embodiments of the present disclosure;

FIG. 8 is a plan view of the semiconductor memory device of FIGS. 6 and 7; and

FIGS. 9A-20A and 9B-20B are cross-sectional views illustrating intermediate steps of a method of fabricating a semiconductor memory device according to some embodiments of the present disclosure.

### DETAILED DESCRIPTION

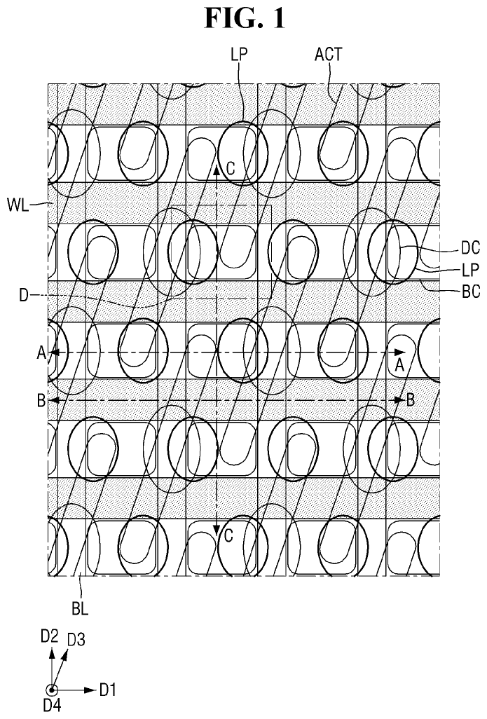

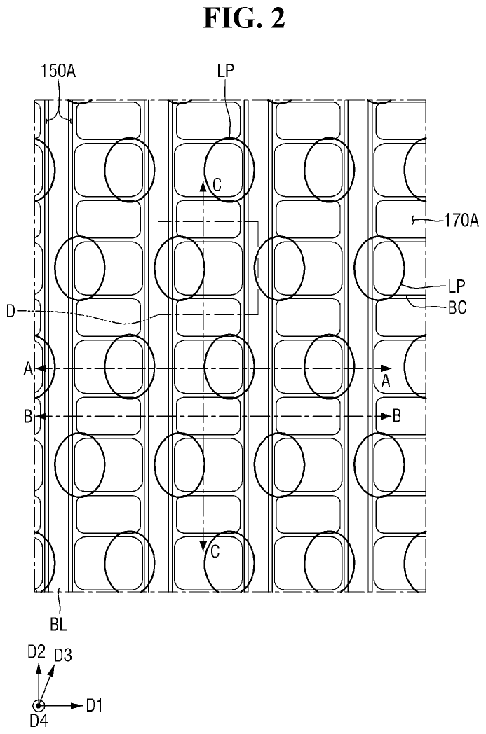

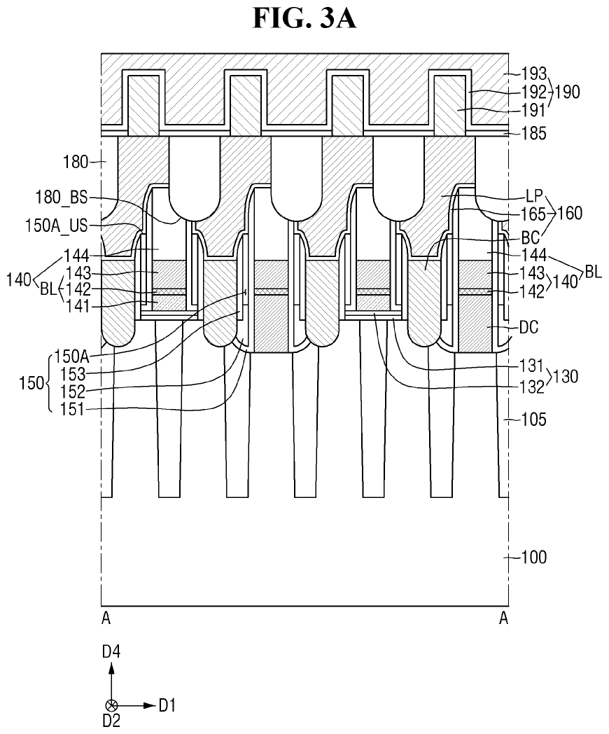

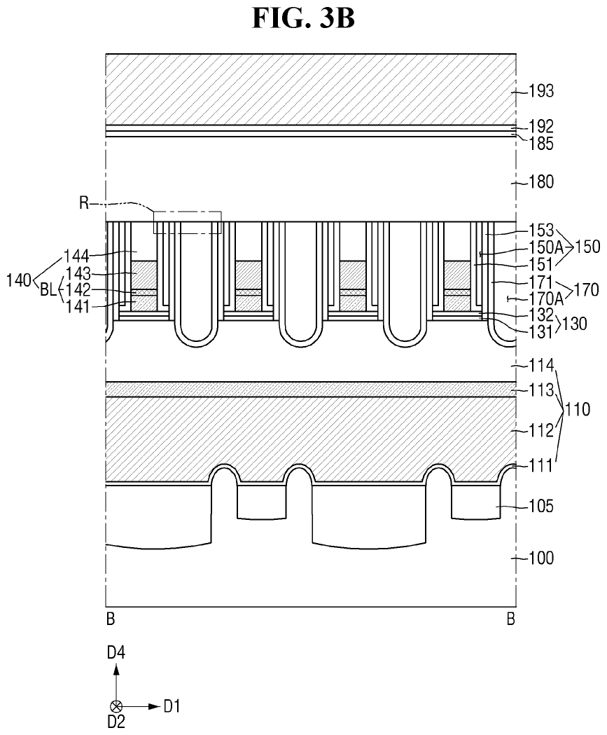

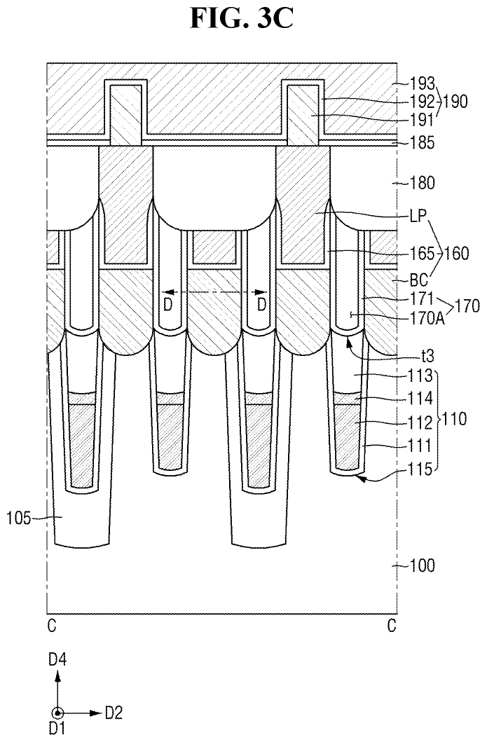

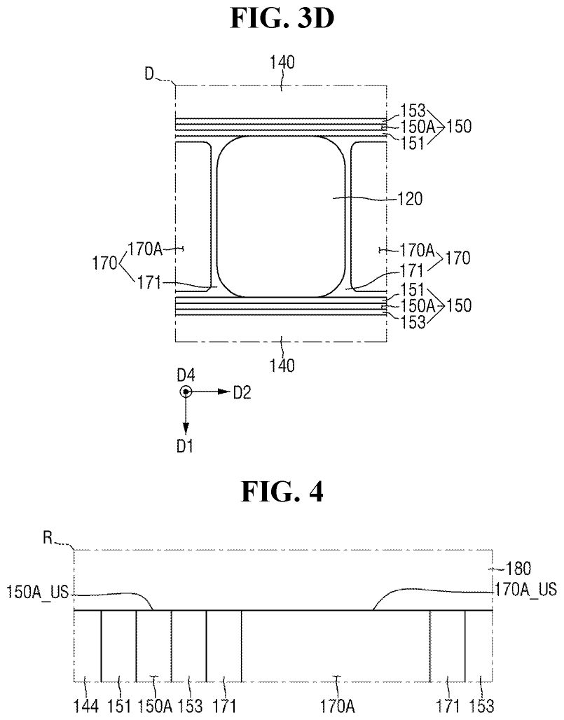

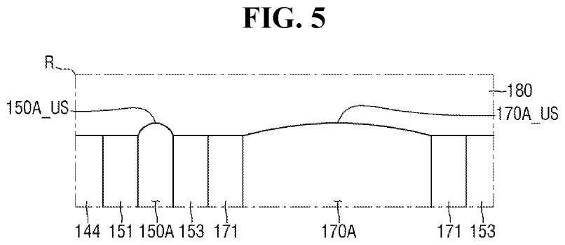

FIG. 1 is a layout view of a semiconductor memory device according to some embodiments of the present disclosure. FIG. 2 is a layout view illustrating bitlines, air spacers, buried contacts, landing pads, and a fence structure of FIG. 1. FIG. 3A is a cross-sectional view taken along line A-A of FIGS. 1 and 2. FIG. 3B is a cross-sectional view taken along line B-B of FIGS. 1 and 2. FIG. 3C is a cross-sectional view taken along line C-C of FIGS. 1 and 2. FIG. 3D is a cross-sectional view taken along line D-D of FIG. 3C. FIGS. 4 and 5 are enlarged cross-sectional views of an area R of FIG. 3B.

The semiconductor memory device is illustrated as being a dynamic random access memory (DRAM), but the present disclosure is not limited thereto.

Referring to FIGS. 1 and 3A-3D, the semiconductor memory device may include a plurality of active regions ACT. The active regions ACT may be defined by device isolation films 105, which are formed in a substrate 100 extending in a first direction D1 and a second direction D2 perpendicular to the first direction. As the design rule of the semiconductor memory device is reduced, the active regions ACT may be arranged in the form of diagonal (or oblique) lines (or bars). For example, the active regions ACT may be formed as bars extending, over a plane defined by the first and second directions D1 and D2, in a third direction D3, which is oblique (i.e., diagonal) to the first direction D1 and the second direction D2. The centers of the active regions ACT may be disposed adjacent to the ends of their respective neighboring active regions ACT. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

A plurality of gate electrodes may be disposed across the active regions ACT. The gate electrodes may extend in parallel to one another. The gate electrodes may be, for example, wordlines WL extending in the first direction. The wordlines WL may be arranged at regular intervals. The width of, and the distance between, the wordlines WL may be determined by the design rule of the semiconductor memory device.

A plurality of bitlines BL may be disposed on the wordlines WL and may extend in the second direction D2 to intersect the wordlines WL. The bitlines BL may extend in parallel to one another. The bitlines BL may be arranged at regular intervals. The width of, and the distance between, the bitlines BL may be determined by the design rule of the semiconductor memory device.

The semiconductor memory device may include a variety of contact arrays, which are formed in the active regions ACT. The contact arrays may include, for example, direct contacts DC, buried contacts BC, and landing pads LP.

Here, the direct contacts DC may be contacts electrically connecting the active regions ACT to the bitlines BL. The buried contacts BC may be contacts connecting the active regions ACT to lower electrodes 191 of capacitors 190. The contact areas between the buried contacts BC and the active regions ACT may be small. Thus, the landing pads LP, which are conductive, may be provided to enlarge the contact areas with the active regions ACT and with the lower electrodes 191.

The landing pads LP may be disposed between the active regions ACT and the buried contacts BC and between the buried contacts BC and the lower electrodes 191 in a fourth direction D4 perpendicular to the first direction D1 and the second direction D2. The landing pads LP may be disposed between the buried contacts BC and the lower electrodes 191 in the fourth direction. As the landing pads LP are provided to enlarge the contact areas with the active regions Act and with the lower electrodes 191, the contact resistances between the active regions ACT and the lower electrodes 191 can be reduced.

The direct contacts DC may be connected to bitline connecting regions 103a. The buried contacts BC may be connected to storage connecting regions 103b. As the buried contacts BC are disposed at ends of the active regions ACT, the landing pads LP may be disposed to partially overlap the buried contacts BC, near the ends of the active regions ACT. For example, the buried contacts BC may be formed to overlap with the active regions ACT between the wordlines WL and with the device isolation films 105 between the bitlines BL. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact. Other words used to describe the relationship between elements should be interpreted in a like fashion (e.g., “between” versus “directly between,” “adjacent” versus “directly adjacent,” etc.).

The wordlines WL may be formed to be buried in the substrate 100. The wordlines WL may be arranged across the active regions ACT between the direct contacts DC or between the buried contacts BC. Every two wordlines WL may be disposed to extend across one active region ACT. As the active regions ACT extend in the third direction D3, the wordlines WL may form an angle of less than 90° with the active regions ACT.

The direct contacts DC and the buried contacts BC may be arranged symmetrically. Thus, the direct contacts DC and the buried contacts BC may be arranged on straight lines with one another in the first and second directions D1 and D2. On the contrary, the landing pads LP, unlike the direct contacts DC and the buried contacts BC, may be arranged in a zigzag fashion in the direction in which the bitlines BL extend (i.e., in the second direction D2). Also, the landing pads LP may be disposed to overlap with the bitlines BL in the direction in which the wordlines WL extend (i.e., in the first direction D1). For example, landing pads LP in a first line may overlap with a first side (e.g., left sides) of their respective bitlines BL, and landing pads LP in a second line may overlap with a second side opposite to the first side (e.g., right sides) of their respective bitlines BL.

Referring to FIGS. 1 through 3D, the semiconductor memory device may include the substrate 100, the device isolation films 105, gate structures 110, bitline structures 140, spacer structures 150, the direct contacts DC, contact structures 160, fence structures 170, pad isolation films 180, and the capacitors 190.

The substrate 100 may include the active regions ACT and the device isolation films 105. The substrate 100 may be a bulk silicon substrate or a silicon-on-insulator (SOI) substrate. Alternatively, the substrate 100 may be a silicon substrate or may include or may be formed of, for example, silicon germanium, a silicon germanium-on-insulator (SGOI), indium antimonide, lead tellurium compound, indium arsenide, indium phosphide, gallium arsenide, or gallium antimonide, but the present disclosure is not limited thereto. The substrate 100 will hereinafter be described as being a silicon substrate.

The device isolation films 105 may be formed in the substrate 100. The device isolation films 105 may have a shallow trench isolation (STI) structure having an excellent isolation property. The device isolation films 105 may define the active regions ACT. The device isolation films 105 are illustrated as having inclined side surfaces, but the present disclosure is not limited thereto.

The device isolation films 105 may include or may be formed of silicon oxide, silicon nitride, or a combination thereof, but the present disclosure is not limited thereto. The device isolation films 105 may be single films including one type of insulating material or multi-films including various types of insulating materials.

The gate structures 110 may be buried in the substrate 100. The gate structures 110 may be formed in the substrate 100 and in the device isolation films 105. The gate structures 110 may be formed across the device isolation films 105 and the active regions ACT, which are defined by the device isolation films 105. The gate structures 110 may extend in the first direction D1 and may be arranged in the second direction D2.

The gate structures 110 may include gate trenches 115, gate insulating films 111, gate electrodes 112, gate capping conductive films 113, and gate capping films 114, which are formed in the substrate 100 and the device isolation films 105. Here, the gate electrodes 112 may correspond to the wordlines WL. Alternatively, the gate structures 110 may not include the gate capping conductive films 113.

The gate insulating films 111 may extend along sidewalls and bottoms of the gate trenches 115. The gate insulating films 111 may extend along the profiles of at least parts of the gate trenches 115. The gate insulating films 111 may include or may be formed of at least one of, for example, silicon oxide, silicon nitride, silicon oxynitride, or a high-k material having a greater dielectric constant than silicon oxide. The high-k material may include or may be formed of at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

The gate electrodes 112 may be formed on the gate insulating films 111. The gate electrodes 112 may fill parts of the gate trenches 115. The gate capping conductive films 113 may extend along the top surfaces of the gate electrodes 112.

The gate electrodes 112 may include or may be formed of at least one of a metal, a metal alloy, a conductive metal nitride, a conductive metal carbonitride, a conductive metal carbide, a metal silicide, a doped semiconductor material, a conductive metal oxynitride, and a conductive metal oxide. The gate electrodes 112 may include or may be formed of at least one of, for example, TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and a combination thereof, but the present disclosure is not limited thereto. The gate capping conductive films 113 may include or may be formed of, for example, polysilicon or polysilicon germanium, but the present disclosure is not limited thereto.

The gate capping films 114 may be disposed on the gate electrodes 112 and the gate capping conductive films 113. The gate capping films 114 may fill parts of the gate trenches 115 that are not filled with the gate electrodes 112 and the gate capping conductive films 113. The gate insulating films 111 may extend along sides of the gate capping films 114, but the present disclosure is not limited thereto. The gate capping films 114 may include or may be formed of at least one of, for example, silicon nitride (SiN), silicon oxynitride (SiON), silicon oxide (SiO₂), silicon oxynitride (SiCN), silicon oxycarbonitride (SiOCN), and a combination thereof.

Although not specifically illustrated, impurity-doped regions may be formed on at least one side of each of the gate structures 110. The impurity-doped regions may be source/drain regions of transistors.

The bitline structures 140 may include the bitlines BL and line capping films 144. The bitlines BL may be formed on the substrate 100 and the device isolation films 105 where the gate structures 110 are formed. The bitlines BL may intersect the device isolation films 105 and the active regions ACT, which are defined by the device isolation films 105. The bitlines BL may be formed to intersect the gate structures 110.

The bitlines BL may be multi-films. The bitlines BL may include, for example, first conductive films 141, second conductive films 142, and third conductive films 143. The first conductive films 141, the second conductive films 142, and the third conductive films 143 may be sequentially stacked on the substrate 100 and the device isolation films 105. The bitlines BL are illustrated as being triple films, but the present disclosure is not limited thereto.

The first conductive films 141, the second conductive films 142, and the third conductive films 143 may include or may be formed of at least one of, for example, a semiconductor material doped with impurities, a conductive silicide compound, a conductive metal nitride, a metal, and a metal alloy. For example, the first conductive films 141 may include or may be formed of a doped semiconductor material, the second conductive films 142 may include or may be formed of at least one of a conductive silicide compound and a conductive metal nitride, and the third conductive films 143 may include or may be formed of at least one of a metal and a metal alloy. However, the present disclosure is not limited to this example.

The direct contacts DC may be formed between the bitlines BL and the substrate 100. That is, the bitlines BL may be formed on the direct contacts DC. For example, the direct contacts DC may be formed at the intersections between the bitlines BL and middle parts of the active regions ACT, which are in the shape of long islands. The direct contacts DC may be formed between the active regions ACT and the bitlines BL.

The direct contacts DC may electrically connect the bitlines BL and the substrate 100. The direct contacts DC may include or may be formed of at least one of, for example, a semiconductor material doped with impurities, a conductive silicon compound, a conductive metal nitride, and a metal.

In areas that overlap with the top surfaces of the direct contacts DC, the bitlines BL may include the second conductive films 142 and the third conductive films 143. In areas that do not overlap with the top surfaces of the direct contacts DC, the bitlines BL may include the first conductive films 141, the second conductive films 142, and the third conductive films 143.

The line capping films 144 may be disposed on the bitlines BL. The line capping films 144 may extend in the second direction D2 along the top surfaces of the bitlines BL. The line capping films 144 may include or may be formed of at least one of, for example, silicon nitride, silicon oxynitride, silicon carbonitride, and silicon oxycarbonitride. The line capping films 144 may include or may be formed of, for example, silicon nitride films. The line capping films 144 are illustrated as being single films, but the present disclosure is not limited thereto.

Insulating films 130 may be formed on the substrate 100 and the device isolation films 105. The insulating films 130 may be formed on parts of the substrate 100 where the direct contacts DC are not formed and on the device isolation films 105. The insulating films 130 may be formed between the substrate 100 and the bitlines BL and between the device isolation films 105 and the bitlines BL.

The insulating films 130 are illustrated as being single films, but may be multi-films including first insulating films 131 and second insulating films 132. For example, the first insulating films 131 may include silicon oxide films, and the second insulating films 132 may be silicon nitride films. However, the present disclosure is not limited to this example.

The spacer structures 150 may be disposed on sidewalls of the bitline structures 140. On bitlines BL where the direct contacts DC are formed, the spacer structures 150 may be disposed on the substrate 100 and the device isolation films 105, on sidewalls of the bitlines BL, the line capping films 144, and the direct contacts DC. On bitlines BL where the direct contacts DC are not formed, the spacer structures 150 may be disposed on the insulating films 130, on sidewalls of the line capping films 144 and the bitline structures 140.

The spacer structures 150 may be multi-films including various types of insulating materials. The spacer structures 150 may include, for example, air spacers 150A, first spacers 151, second spacers 152, and third spacers 153. The term “air spacer” as used herein refers to a space or gap that includes atmospheric air or other gases that may exist during a manufacturing process.

The first spacers 151 may extend along at least parts of sides of the bitline structures 140. On the bitlines BL formed on the direct contacts DC, as illustrated in FIG. 3A for example, the first spacers 151 may extend along the sidewalls of the line capping films 144, the bitlines BL, and the direct contacts DC. On the bitlines BL where the direct contacts DC are not formed, as illustrated in FIG. 3B for example, the first spacers 151 may extend along the sidewalls of the bitlines BL and the sidewalls of the line capping films 144 and along the top surfaces of the insulating films 130. The spacer structures 150 may extend in the second direction D2.

Referring to FIG. 3A, which is a cross-sectional view, taken along the first direction D1, of the contact structures 160, the width of upper parts of the fence structures 170 may be smaller than the width of lower parts of the spacer structures 150. The top surfaces of the lower parts of the spacer structures 150 may be positioned above the top surfaces of the buried contacts BC. Referring to FIG. 3B, which is a cross-sectional view, taken along the first direction D1, of the gate structures 110 or the fence structures 170, the width of the spacer structures 150 may be uniform. That is, the width of the spacer structures 150 may be uniform on the gate structures 110.

The second spacers 152 may be disposed on the first spacers 151. The second spacers 152 may be isolated from the device isolation films 105 by the first spacers 151. The second spacers 152 may extend along the sides of the direct contacts DC. The second spacers 152 may be disposed between the first spacers 151 and the buried contacts BC in the first direction D1. The second spacers 152 may define the bottom surfaces of the air spacers 150A.

On the bitlines BL formed on the direct contacts DC as illustrated in FIG. 3A for example, sidewalls of the air spacers 150A may be defined by the first spacers 151 and the third spacers 153, and the bottom surfaces of the air spacers 150A may be defined by the second spacers 152. On the bitlines BL where the direct contacts DC are not formed as illustrated in FIG. 3B for example, the sidewalls of the air spacers 150A may be defined by the first spacers 151 and the third spacers 153, and the bottom surfaces of the air spacers 150A may be defined by the first spacers 151.

The first spacers 151, the second spacers 152, and the third spacers 153 may include or may be formed of at least one of silicon oxide, silicon oxynitride, silicon nitride, and a combination thereof, but the present disclosure is not limited thereto. Alternatively, the first spacers 151, the second spacers 152, and the third spacers 153 may include or may be formed of silicon nitride.

The contact structures 160 may be disposed on sides of the bitline structures 140. The contact structures 160 may be isolated from the bitline structures 140 by the spacer structures 150. The spacer structures 150 may electrically insulate the bitline structures 140 and the contact structures 160.

The contact structures 160 may include the buried contacts BC, barrier films 165, and the landing pads LP, which are sequentially stacked on the substrate 100 in the fourth direction D4.

The buried contacts BC may be formed on the substrate 100, between the bitline structures 140. The buried contacts BC may be interposed in regions defined by the gate structures 110 and the bitline structures 140. The buried contacts BC may be arranged in the second direction D2 between bitline structures 140 that are adjacent to one another in the first direction D1.

The buried contacts BC may overlap with the substrate 100 and the device isolation films 105, between the bitlines BL. The buried contacts BC may electrically connect the active regions ACT of the substrate 100 and the landing pads LP through the insulating films 130. The active regions ACT, which are connected to the buried contacts BC, may function as source and drain regions.

The buried contacts BC may include or may be formed of at least one of, for example, a semiconductor material doped with impurities, a conductive silicide compound, a conductive metal nitride, and a metal.

The barrier films 165 may cover the buried contacts BC, the spacer structures 150, and the bitline structures 140. The barrier films 165 may extend conformally along the top surfaces of the buried contacts BC, the sidewalls and the top surfaces of the spacer structures 150, and the top surfaces of the bitline structures 140.

The barrier films 165 may include or may be formed of, for example, a conductive metal nitride such as titanium nitride, tantalum nitride, or tungsten nitride.

The landing pads LP may be disposed on the barrier films 165. The landing pads LP may be electrically connected to the buried contacts BC through the barrier films 165.

The top surfaces of the landing pads LP may be higher than the top surfaces of the bitline structures 140. The landing pads LP may cover parts of the top surfaces of the bitline structures 140. For example, the landing pads LP may overlap with parts of the top surfaces of the bitline structures 140.

The landing pads LP may include or may be formed of at least one of, for example, a semiconductor material doped with impurities, a conductive silicide compound, a conductive metal nitride, a conductive metal carbide, a metal, and a metal alloy.

The pad isolation films 180 may be formed on the landing pads LP and the bitline structures 140. The pad isolation films 180 may extend from the top surfaces of the landing pads LP, and bottom surfaces of the pad isolation films 180 may be lower than the top surfaces of the bitline structures 140. Accordingly, the landing pads LP may be isolated by the bitline structures 140 and the pad isolation films 180. The bottom surfaces of the pad isolation films 180 may be positioned above, for example, the top surfaces of the line capping films 144. That is, the pad isolation films 180 may be in contact with the line capping films 144.

Lowermost bottom surfaces 180_BS of the pad isolation films 180 may be positioned above top surfaces 150A_US of the air spacers 150A. That is, the air spacers 150A may not be in contact with the pad isolation films 180. The top surfaces 150A_US of the air spacers 150A may be defined by the barrier films 165.

The fence structures 170 may be disposed on the substrate 100 and the device isolation films 105. The fence structures 170 may be formed to overlap with the gate structures 110, which are formed in the substrate 100 and the device isolation films 105, in a fourth direction D4. The fourth direction D4 may intersect the first and second directions D1 and D2.

The fence structures 170 may be disposed between the spacer structures 150, which are adjacent to one another. The fence structures 170 may be disposed between the contact structures 160, which are adjacent to one another. The fence structures 170 may fill the gaps between the spacer structures 150 and between the contact structures 160. Accordingly, the contact structures 160, which are arranged in the second direction D2, may be isolated by the fence structures 170.

Specifically, the fence structures 170 may fill third trenches t3. The bottoms of the third trenches t3 may be defined by the gate capping films 114. Sidewalls of the third trenches t3 may be defined by the contact structures 160 and the spacer structures 150. For example, the bottoms of the third trenches t3 may be disposed in the gate capping films 114.

The fence structures 170 may include first fence liners 171 and second fence liners 170A. The first fence liners 171 may extend along the bottoms and sidewalls of the third trenches t3. The second fence liners 170A may be disposed on the first fence liners 171 to fill the third trenches t3.

The fence structures 170 may be in contact with the pad isolation films 180. The top surfaces of the fence structures 170 may be defined by the pad isolation films 180.

The first fence liners 171 may include or may be formed of at least one of, for example, silicon oxide, silicon nitride, silicon oxynitride, and a combination thereof. For example, the first fence liners 171 may include or may be formed of silicon nitride.

The second fence liners 170A may be formed by air. Top surfaces 173_US of the second fence liners 170A may be defined by the pad isolation films 180. Sidewalls of the second fence liners 170A may be defined by the first fence liners 171.

Referring to FIG. 3D, the buried contacts BC may be disposed in regions defined by the air spacers 150A and the second fence liners 170A, which are formed by air. The buried contacts BC may overlap with the air spacers 150A in the first direction D1 and with the second fence liners 170A in the second direction D2. The air spacers 150A may extend in the second direction D2 to overlap with the second fence liners 170A in the first direction D1. The air spacers 150A may be isolated from the second fence liners 170A by the first spacers 151 and the first fence liners 171. The second fence liners 170A may be disposed between air spacers 150A that are adjacent to one another in the first direction D1.

Referring to FIGS. 2 and 3D, the width, in the first direction D1, of the second fence liners 170A may be greater than the distance between the buried contacts BC and the second fence liners 170A. The width, in the second direction D2, of the second fence liners 170A may be greater than the distance between the buried contacts BC and the second fence liners 170A.

As the integration density of the semiconductor memory device increases, the influence of parasitic capacitance and a leakage current gradually increases. For example, as the distance between conductive patterns of a DRAM decreases, the parasitic capacitance between the conductive patterns may increase.

However, as the semiconductor memory device includes the air spacers 150A and the second fence liners 170A, which are formed by air, the parasitic capacitance between the bitlines BL and the buried contacts BC can be reduced. Accordingly, the operating properties of the semiconductor memory device can be improved.

Referring again to FIGS. 3A through 3C, etching stopper films 185 may be disposed on the pad isolation films 180 and the landing pads LP. The etching stopper films 185 may include or may be formed of at least one of, for example, silicon nitride, silicon carbonitride, silicon boron nitride, (SiBN), silicon oxynitride, and silicon oxycarbide.

The capacitors 190 may be disposed on the landing pads LP. The capacitors 190 may be electrically connected to the landing pads LP. As a result, the capacitors 190 may be electrically connected to source and drain regions that are connected to the buried contacts BC. Accordingly, the capacitors 190 can store electric charge therein.

Parts of the capacitors 190 may be disposed in the etching stopper films 185. The capacitors 190 may include the lower electrodes 191, a capacitor dielectric film 192, and an upper electrode 193. The capacitors 190 may store electric charge in the capacitor dielectric film 192 based on electric potential differences generated between the lower electrodes 191 and the upper electrode 193.

The lower electrodes 191 may be disposed on the landing pads LP. The lower electrodes 191 may have a pillar shape, but the present disclosure is not limited thereto. Alternatively, the lower electrodes 191 may have a cylindrical shape. The capacitor dielectric film 192 may be formed on the lower electrodes 191. The capacitor dielectric film 192 may be formed along the profiles of the lower electrodes 191. The upper electrode 193 may be formed on the capacitor dielectric films 192. The upper electrode 193 may surround outer sidewalls of the lower electrodes 191.

For example, the capacitor dielectric film 192 may be disposed to overlap vertically (i.e., in the fourth direction D4) with the upper electrode 193. In another example, the capacitor dielectric film 192 may include a first part vertically overlapping with the upper electrode 193 and a second part not vertically overlapping with the upper electrode 193. That is, the second part of the capacitor dielectric film 192 may be part of the capacitor dielectric film 192 not being covered by the upper electrode 193.

The lower electrodes 191 and the upper electrode 193 may include or may be formed of, for example, a doped semiconductor material, a conductive metal nitride (e.g., titanium nitride, tantalum nitride, niobium nitride or tungsten nitride), a metal (e.g., ruthenium, iridium, titanium, or tantalum), or a conductive metal oxide (e.g., iridium oxide or niobium oxide), but the present disclosure is not limited thereto.

The capacitor dielectric film 192 may include or may be formed of, for example, silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof, but the present disclosure is not limited thereto. The capacitor dielectric film 192 may include or may be formed of a dielectric film including hafnium (Hf). The capacitor dielectric film 192 may have a structure in which a ferroelectric material film and a paraelectric material film are stacked.

Referring to FIG. 4, a top surface 150A_US of an air spacer 150A and a top surface 170A_US of a second fence liner 170A may be defined by a pad isolation film 180. The top surface 150A_US of the air spacer 150A and the top surface 170A_US of the second fence liner 170A may be flat.

Alternatively, referring to FIG. 5, a top surface 150A_US of an air spacer 150A and a top surface 170A_US of a second fence liner 170A may be convex toward a pad isolation film 180.

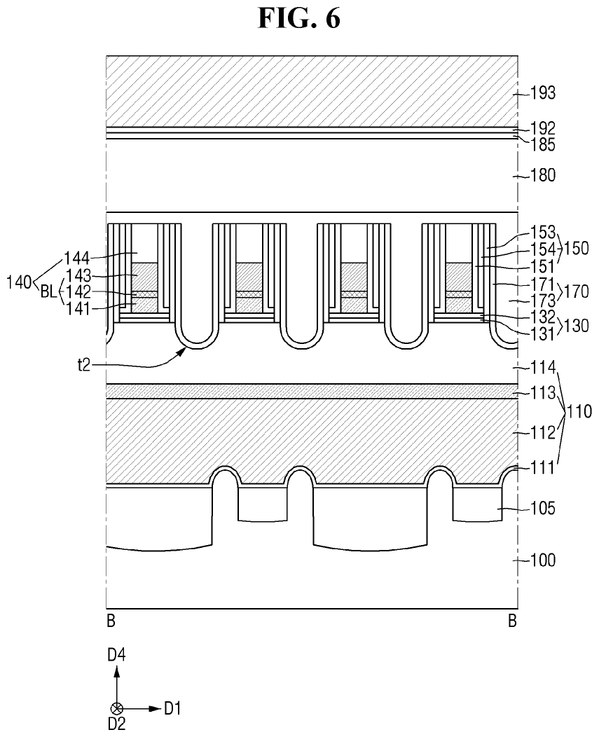

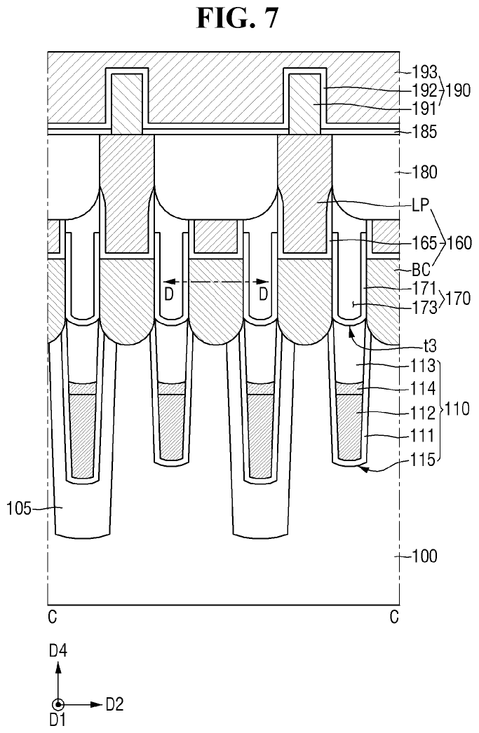

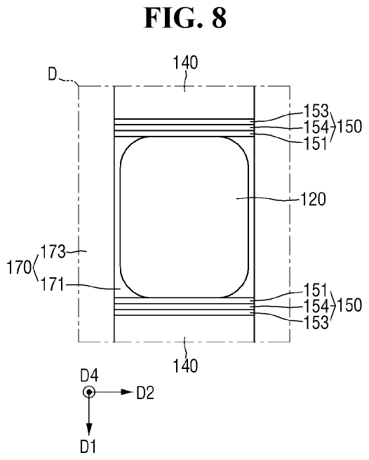

FIGS. 6 and 7 are cross-sectional views of a semiconductor memory device according to some embodiments of the present disclosure. FIG. 8 is a plan view of the semiconductor memory device of FIGS. 6 and 7. FIG. 6 is a cross-sectional view taken along line B-B of FIGS. 1 and 2, FIG. 7 is a cross-sectional view taken along line C-C of FIGS. 1 and 2, and FIG. 8 is a plan view taken along line D-D of FIG. 7. FIG. 8 illustrates an area of the semiconductor memory device of FIGS. 6 and 7 corresponding to an area D of FIGS. 1 and 2.

Referring to FIGS. 6 and 7, fence structures 170 may cover bitline structures 140 and spacer structures 150. The fence structures 170 may extend along the top surfaces of the bitline structures 140 and the top surfaces of the spacer structures 150.

First fence liners 171 may extend along the bottoms and sidewalls of third trenches t3. The first fence liners 171 may also extend along sidewalls of the spacer structures 150.

Second fence liners 173 may be disposed on the first fence liners 171 to extend along the top surfaces of the bitline structures 140, the top surfaces of the spacer structures 150, and the top surfaces of the first fence liners 171. Pad isolation films 180 may be disposed on the second fence liners 173. The bitline structures 140, the spacer structures 150, and the first fence liners 171 may be isolated from the pad isolation films 180 by the second fence liners 173. The second fence liners 173 may have a “T” shape between contact structures 160.

The spacer structures 150 may include fourth spacers 154, instead of the air spacers 150A of FIGS. 1 through 5.

The second fence liners 173 and the fourth spacers 154 may be formed of silicon oxide. The second fence liners 173 and the fourth spacers 154 may be connected to one another. In this case, the boundaries between the second fence liners 173 and the fourth spacers 154 may be undistinguishable.

Referring to FIG. 8, a buried contact BC may be disposed in an isolated region defined by second fence liners 173 and fourth spacers 154. The second fence liners 173 may extend in a first direction D1 to connect the fourth spacers 154, which are spaced apart from each other. The second fence liners 173 may connect the fourth spacers 154, which are spaced apart from each other in the first direction D1. The buried contact BC may overlap with the fourth spacers 154 in the first direction D1 and with the second fence liners 173 in the second direction D2.

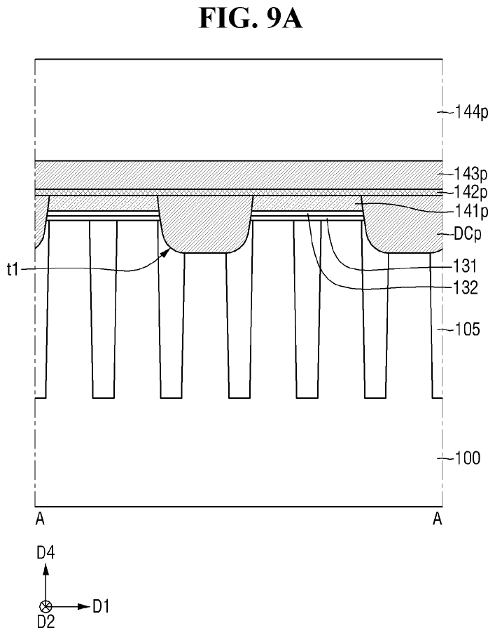

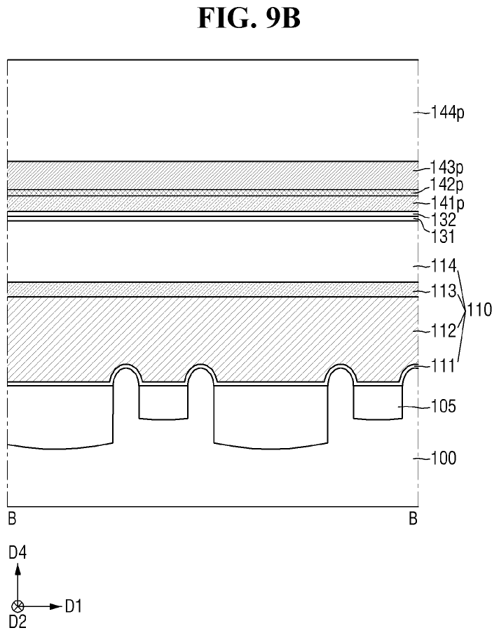

FIGS. 9A through 20B are cross-sectional views illustrating intermediate steps of a method of fabricating a semiconductor memory device according to some embodiments of the present disclosure. FIGS. 9A, 10A, 11A, 12A, 13A, 14A, 15A, 16A, 17A, 18A, 19A, and 20A are cross-sectional views taken along lines A-A of FIGS. 1 and 2. FIGS. 9B, 10B, 11B, 12B, 13B, 14B, 15B, 16B, 17B, 18B, 19B, and 20B are cross-sectional views taken along lines B-B of FIGS. 1 and 2.

Referring to FIGS. 9A and 9B, a substrate 100 including device isolation films 105 and active regions, which are defined by the device isolation films 105, is provided.

A gate structure 110 may be formed in the substrate 100. The gate structure 110 may extend in a first direction D1. The gate structure 110 may include a gate trench 115, a gate insulating film 111, a gate electrode 112, a gate capping film 114, and a gate capping conductive film 113.

A first insulating film 131, a second insulating film 132, and a first pre-conductive film 141p may be sequentially formed on the substrate 100. Thereafter, first trenches t1, which expose parts of the active regions, may be formed in the substrate 100. The first trenches t1 may expose, for example, the centers of the active regions. Thereafter, pre-direct contacts DCp, which fill the first trenches t1, may be formed. Thereafter, a second pre-conductive film 142p, a third pre-conductive film 143p, and a pre-line capping film 144p may be sequentially formed on the first pre-conductive film 141p and the pre-direct contacts DCp.

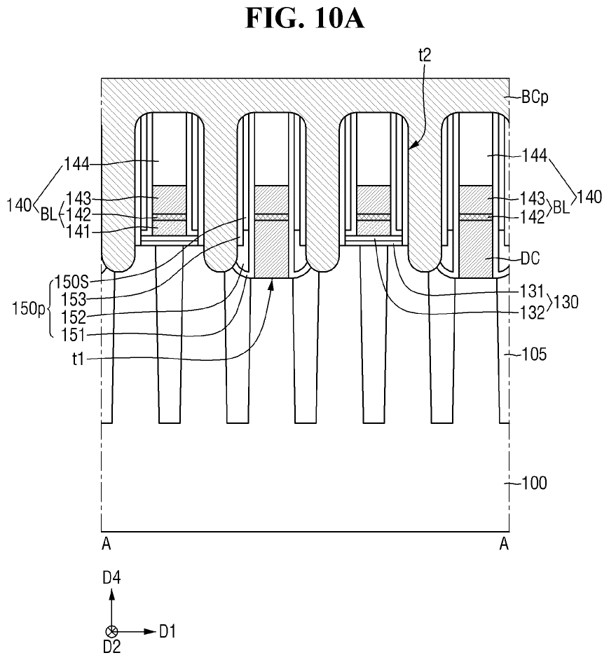

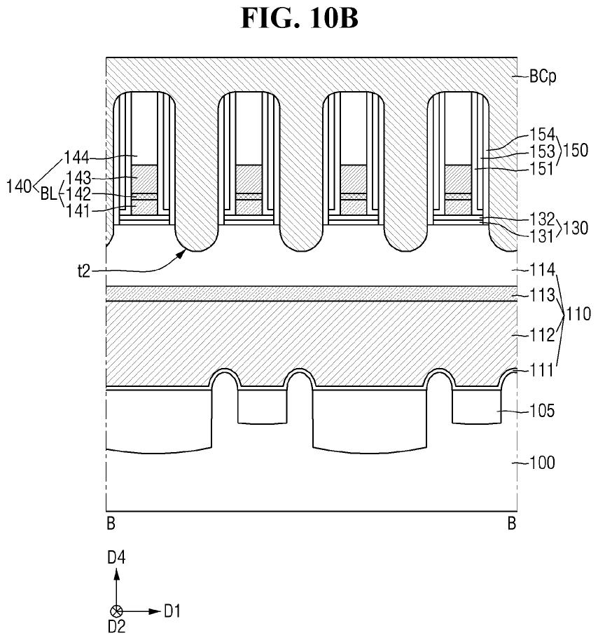

Referring to FIGS. 10A and 10B, the pre-line capping film 144p, the first, second, and third pre-conductive films 141p, 142p, and 143p, and the pre-direct contacts DCp are patterned. As a result, bitline structures 140, which extend in a second direction D2 across direct contacts DC, the active regions, and wordline structures, may be formed. For example, the width of the bitline structures 140 and the width of the direct contacts DC may be smaller than the width of the first trenches t1. That is, the bitline structures 140 and the direct contacts DC may completely fill the first trenches t1.

Thereafter, pre-spacer structures 150p may be formed on sidewalls of the bitline structures 140. The pre-spacer structures 150p may include first spacers 151, second spacers 152, sacrificial spacers 150S, and third spacers 153. The sacrificial spacers 150S may be formed of a material having etching selectivity with respect to the first spacers 151, the second spacers 152, and the third spacers 153.

For example, the sacrificial spacers 150S may include or may be formed of silicon oxide, and the first spacers 151, the second spacers 152, and the third spacers 153 may include or may be formed of silicon nitride.

Second trenches t2 are formed between the bitline structures 140. The second trenches t2 may expose parts of the substrate 100 between the pre-spacer structures 150p, which are formed on the sidewalls of the bitline structures 140, between bitline structures 140 that are adjacent to one another in the first direction D1. The second trenches t2 may expose the top surface of the gate capping conductive film 113, which is formed in the substrate 100.

Thereafter, pre-buried contacts BCp, which fill the second trenches t2 and cover the bitline structures 140 and the pre-spacer structures 150p, are formed.

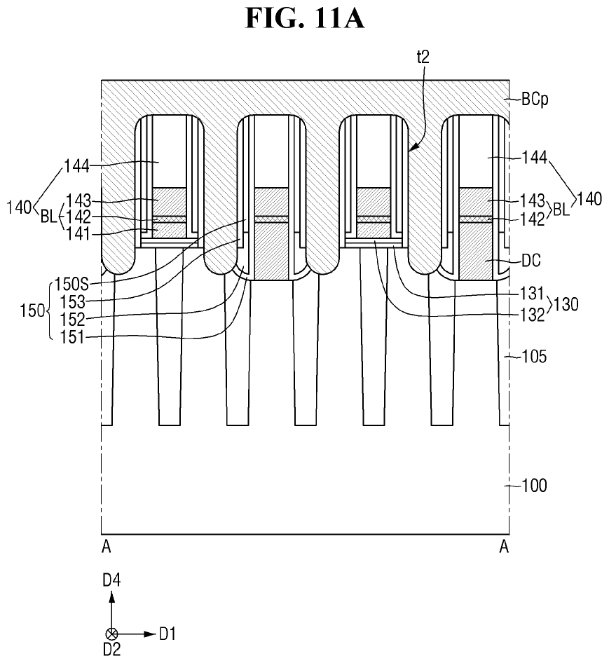

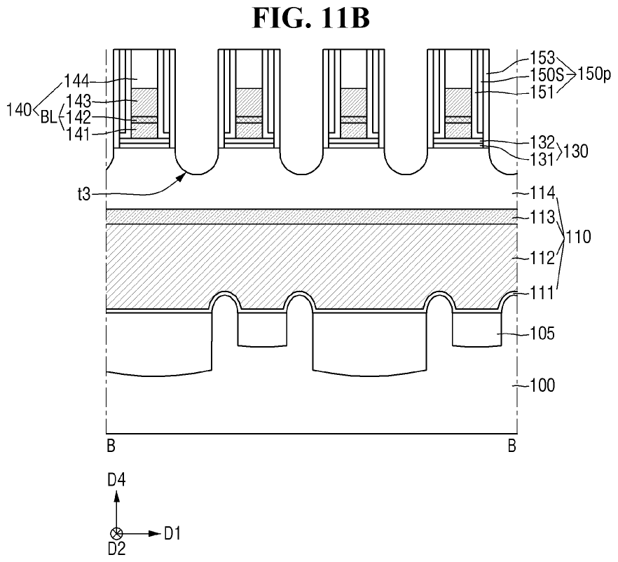

Referring to FIGS. 11A and 111B, pre-buried contacts BCp on the gate structure 110 are removed, and as a result, third trenches t3 are formed. The top surfaces of bitline structures 140 and pre-spacer structures 150p on the gate structure 110 may be exposed. The bottoms of the third trenches t3 may coincide with the bottoms of the second trenches t2 of FIGS. 10A and 10B or may be positioned below the bottoms of the second trenches t2 of FIGS. 10A and 10B.

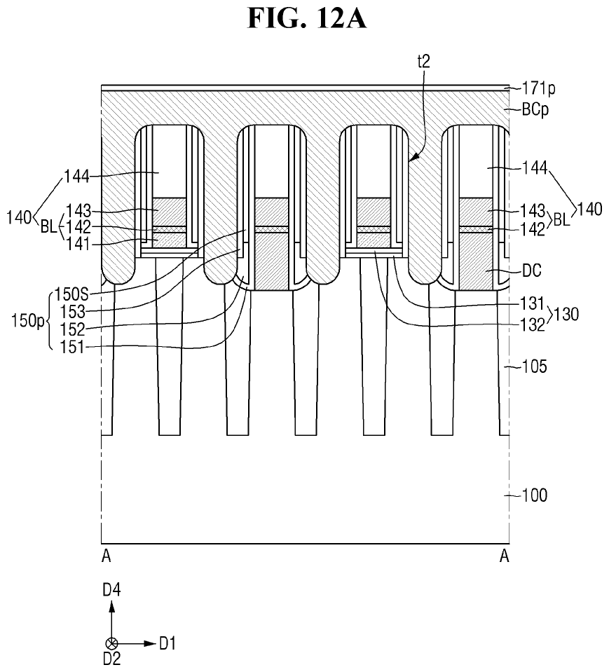

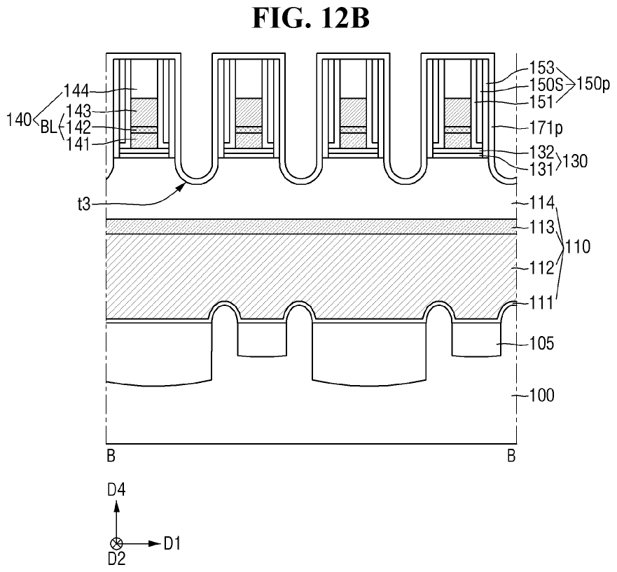

Referring to FIGS. 12A and 12B, first pre-fence liners 171p are formed. The first pre-fence liners 171p may be conformally formed along the top surfaces of the pre-buried contacts BCp, the top surfaces of the bitline structures 140 and the pre-spacer structures 150p on the gate structure 110, and the bottoms and sidewalls of the third trenches t3.

The first pre-fence liners 171p may include or may be formed of, for example, silicon nitride.

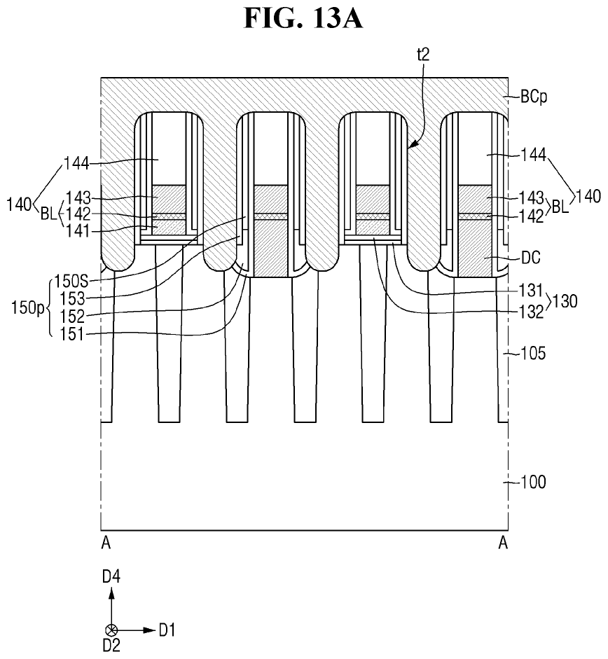

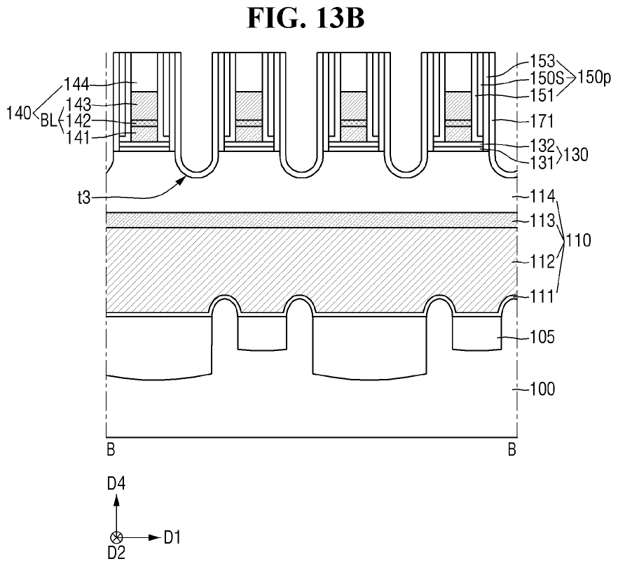

Referring to FIGS. 13A and 13B, parts of the first pre-fence liners 171p that are on the bitline structures 140 and the spacer structures 150 are etched. As a result, first fence liners 171, which extend along the sidewalls and bottoms of the third trenches t3, are formed, and the top surfaces of the sacrificial spacers 150S and the top surfaces of the pre-buried contacts BCp are exposed.

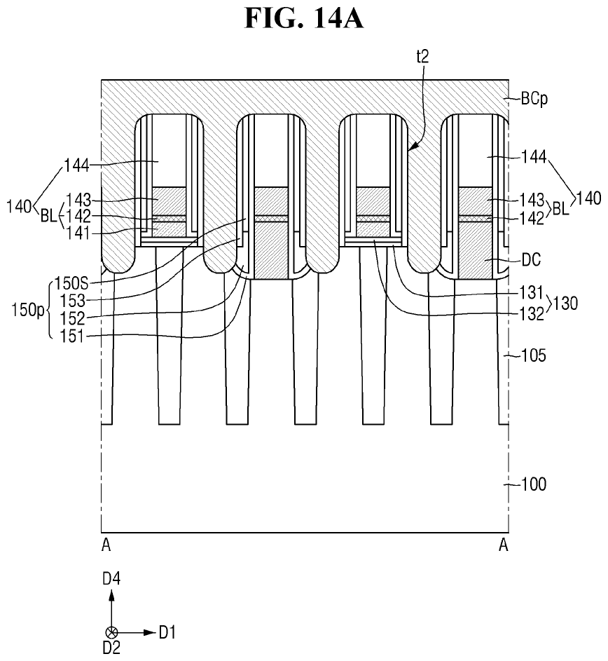

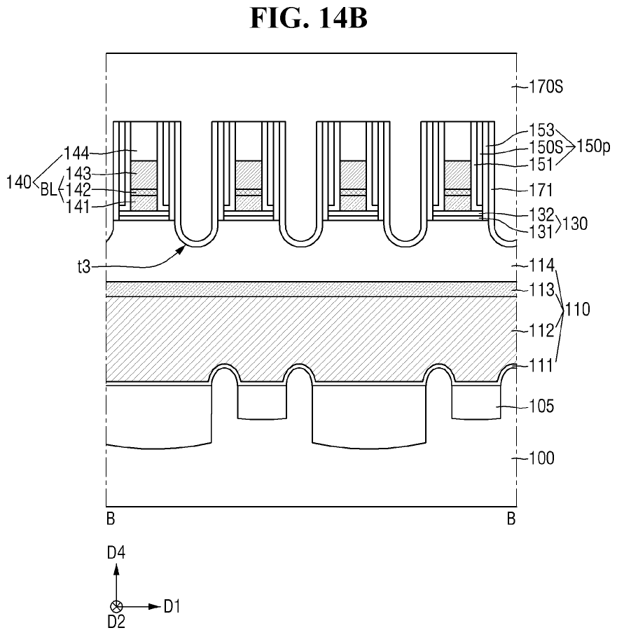

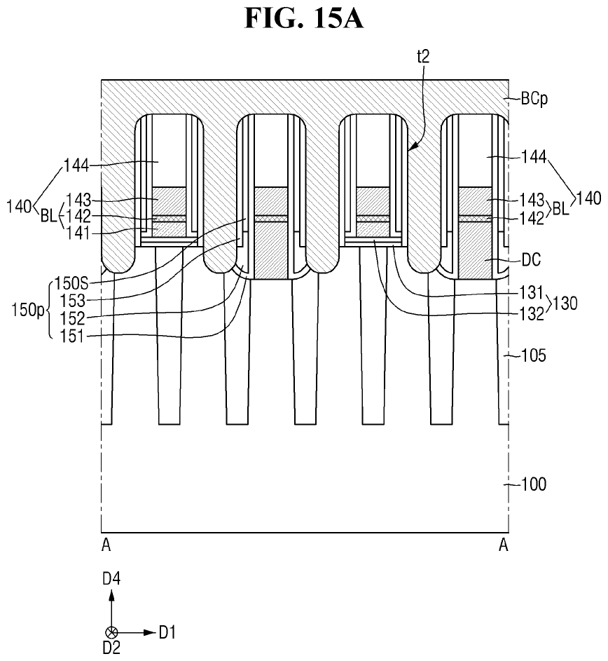

Referring to FIGS. 14A and 14B, a sacrificial fence liner 170S, which covers the bitline structures 140, the pre-spacer structures 150p, and the first fence liners 171 on the gate structure 110, may be formed. The sacrificial fence liner 170S may be formed on the first fence liners 171 to fill the third trenches t3. The sacrificial fence liners 170S may extend along the top surfaces of the bitline structures 140, the top surfaces of the pre-spacer structures 150p, and the top surfaces of the first fence liners 171. In some embodiments, the top surface of the sacrificial fence liner 170S may be positioned on substantially the same plane as the top surfaces of the pre-buried contacts BCp.

The sacrificial fence liner 170S may include or may be formed of the same material as the sacrificial spacers 150S. The sacrificial fence liner 170S may include or may be formed of, for example, silicon oxide. The sacrificial fence liner 170S may be in contact with the top surfaces of the sacrificial spacers 150S. The sacrificial fence liner 170S may be connected to the sacrificial spacers 150S.

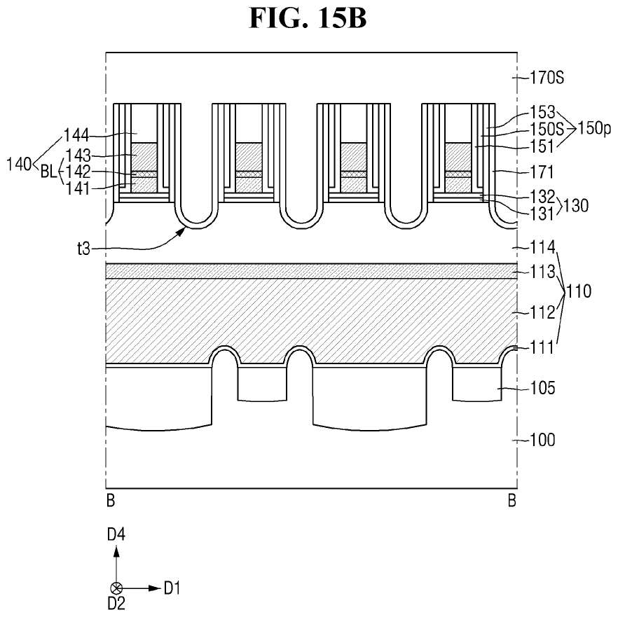

Referring to FIGS. 15A and 15B, part of the sacrificial fence liner 170S may be etched. The sacrificial fence liner 170S may be etched, but not to the extent that the bitline structures 140 and the pre-spacer structures 150p on the gate structure 110 are exposed.

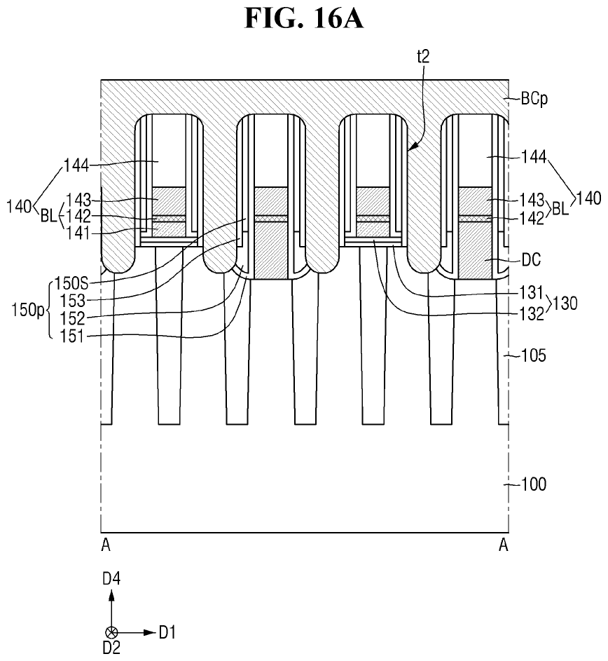

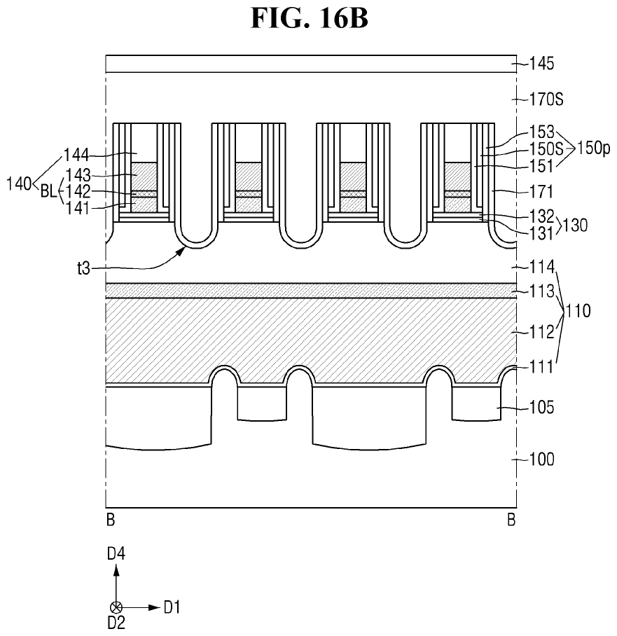

Referring to FIGS. 16A and 16B, a sacrificial film 145 may be formed on the sacrificial fence liner 170S. In some embodiments, the top surface of the sacrificial film 145 may be positioned on substantially the same plane as the top surfaces of the pre-buried contacts BCp.

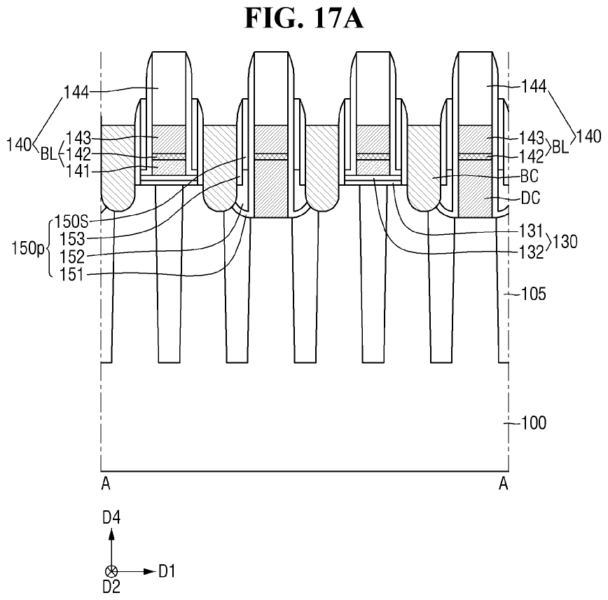

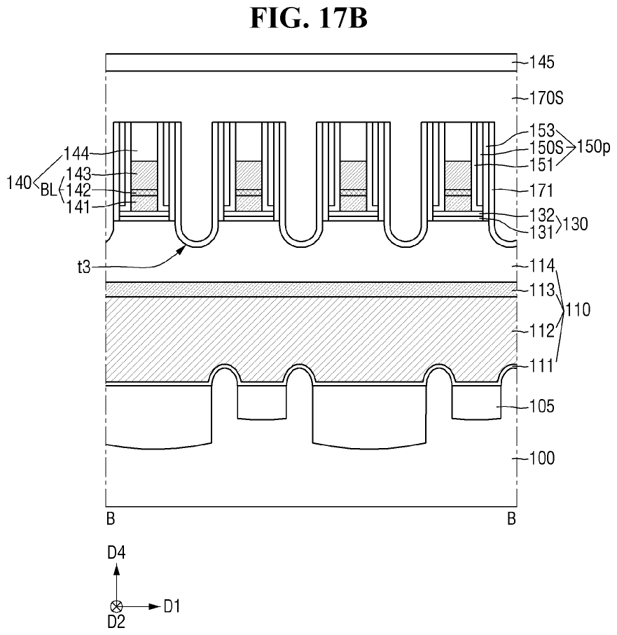

The sacrificial film 145 may be thick enough to protect the sacrificial fence liner 170S during the etching of the pre-spacer structures 150p, which will be described later with reference to FIGS. 17A and 17B.

The sacrificial film 145 may include or may be formed of, for example, silicon nitride.

Referring to FIGS. 17A and 17B, parts of the pre-buried contacts BCp may be etched, and as a result, buried contacts BC may be formed. The buried contacts BC, which expose the top surfaces of the bitline structures 140 and the pre-spacer structures 150p, may be formed by etching back the pre-buried contacts BCp.

Thereafter, upper parts of the pre-spacer structures 150p may be partially etched. For example, upper parts of the sacrificial spacers 150S and the third spacers 153 may be etched. In some embodiments, the top surfaces of the sacrificial spacers 150S and the third spacers 153 may be positioned above the top surfaces of the top surfaces of the buried contacts BC. In this case, the sacrificial fence liner 170S may not be etched by the sacrificial film 145.

Accordingly, the top surfaces of sacrificial spacers 150S and third spacers 153 on the active regions and the device isolation films 105 of the substrate 100, rather than on the gate structure 110, may be positioned below the top surfaces of the first spacers 151. The width of upper parts of pre-spacer structures 150p on the active regions and the device isolation films 105 of the substrate 100 may be smaller than the width of lower parts of the pre-spacer structures 150p on the active regions and the device isolation films 105 of the substrate 100. The upper parts of the pre-spacer structures 150p may include the first spacers 151, and the lower parts of the pre-spacer structures 150p may include the first spacers 151, the sacrificial spacers 150S, the third spacers 153, and/or the second spacers 152. As the upper parts of the spacer structures 150 have a smaller width than the lower parts of the spacer structures 150, the margin for the contact between landing pads LP and the buried contacts BC can be improved.

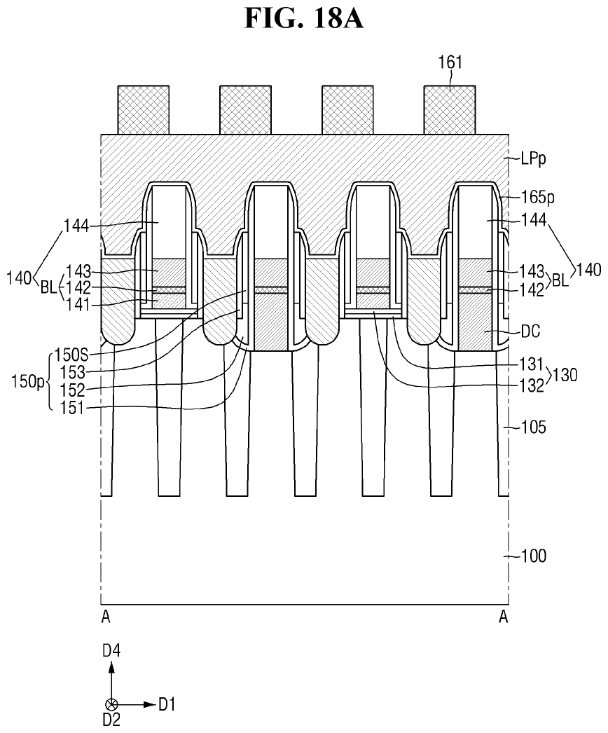

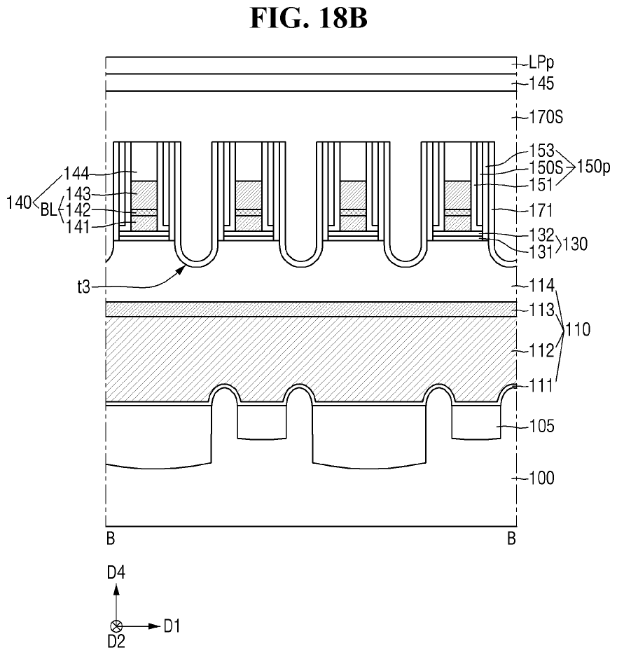

Referring to FIGS. 18A and 18B, a barrier film 165p may be formed along the top surfaces of the bitline structures 140, the top surfaces and side surfaces of the spacer structures 150, the top surfaces of the buried contacts BC, and the sacrificial film 145. The barrier film 165p may be conformally formed.

Thereafter, a pre-landing pad LPp, which covers the barrier film 165, may be formed. The top surface of the pre-landing pad LPp may be positioned above the top surfaces of the bitline structures 140.

Thereafter, mask patterns 161 may be formed on the pre-landing pad LPp.

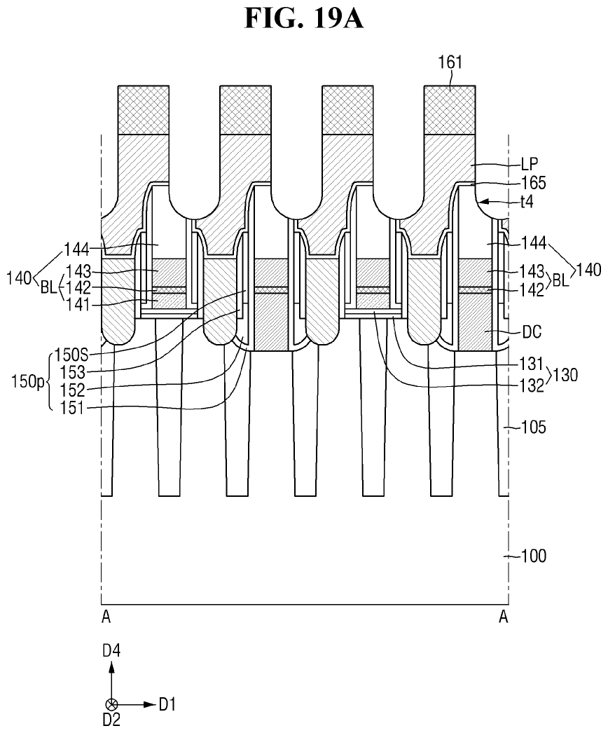

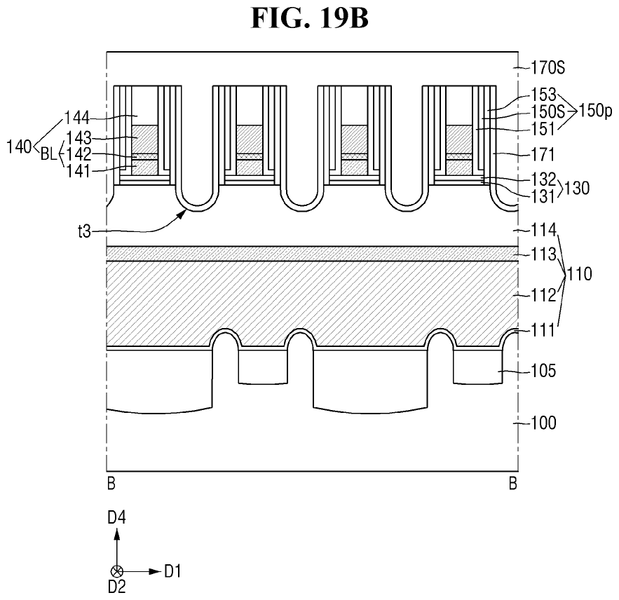

Referring to FIGS. 19A and 19B, parts of the pre-landing pad LPp, the barrier film 165, the sacrificial film 145, the bitline structures 140, and the pre-spacer structures 150p, exposed by the mask patterns 161 may be etched. As a result, fourth trenches t4 and landing pads LP, which are isolated by the fourth trenches t4, may be formed, and the sacrificial fence liner 170S may be exposed.

In some embodiments, part of the sacrificial fence liner 172S may also be etched. In some embodiments, the bottoms of the fourth trenches t4 may be positioned above the sacrificial spacers 150S. The sacrificial spacers 150S may not be exposed by the fourth trenches t4.

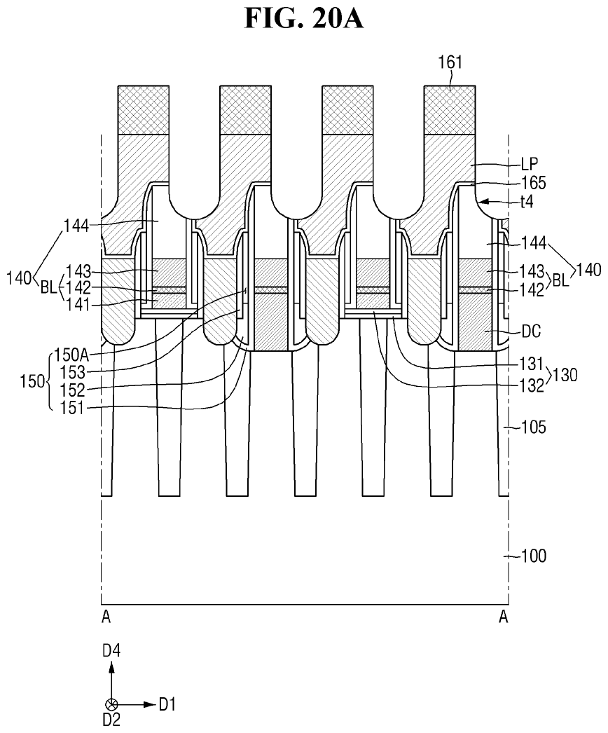

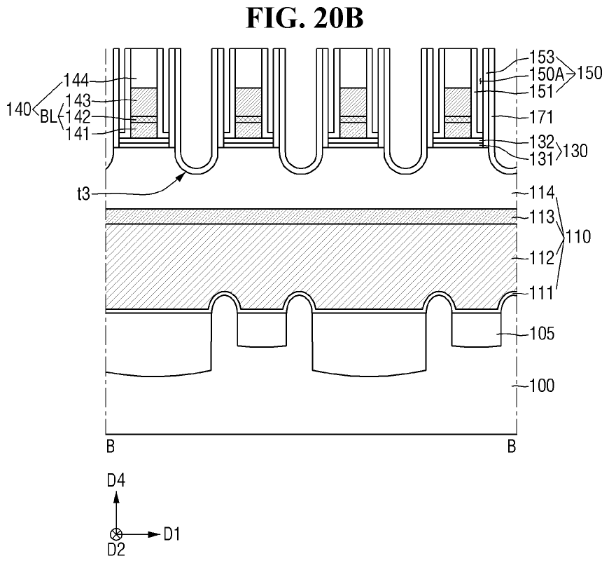

Referring to FIGS. 20A and 20B, the sacrificial spacers 150S and the sacrificial fence liner 170S may be removed. As the sacrificial spacers 150S are in contact with the sacrificial fence liner 170S, on the gate structure 110, the sacrificial spacers 150S may be removed along with the sacrificial fence liner 170S during the removal of the sacrificial fence liner 170S. Air spacers 150A may be formed in spaces from which the sacrificial spacer 150S is removed. In this manner, spacer structures 150 including the air spacers 150A may be formed.

As the sacrificial spacers 150S are connected to, and can thus be removed together with, the sacrificial fence liner 170S, the fourth trenches t4 do not need to be formed to expose the sacrificial spacers 150S. Thus, the locations of the bottoms of the fourth trenches t4 can be properly controlled.

The size of the sacrificial fence liner 170S being exposed after the removal of the sacrificial spacers 150S through the fourth trenches t4 may be greater than the size of the sacrificial spacers 150S previously being exposed by the fourth trenches t4. Thus, the sacrificial spacers 150S can be easily removed.

Thereafter, referring again to FIGS. 3B and 3C, pad isolation films 180, which fill the fourth trenches t4, may be formed. Thus, the landing pads LP may form a plurality of isolated regions that are separated from one another by the pad isolation films 180. The pad isolation films 180 may expose the top surfaces of the landing pads LP. In some embodiments, the top surfaces of the pad isolation films 180 may not cover the top surfaces of the landing pads LP.

The top surfaces of the air spacers 150A and the top surfaces of second fence liners 170A may be defined by the pad isolation films 180. The top surfaces of the air spacers 150A and the top surfaces of the second fence liners 170A may be flat, as illustrated in FIG. 4. Alternatively, the top surfaces of the air spacers 150A and the top surfaces of the second fence liners 170A may be convex toward the pad isolation films 180, as illustrated in FIG. 5.

As the sacrificial spacers 150S are not exposed by the fourth trenches t4, the pad isolation films 180 may not be inserted into the fourth trenches t4. Thus, as the air spacers 150A can extend to the barrier film 165, the parasitic capacitance between bitlines BL and the buried contacts BC can be reduced.

Thereafter, an etching stopper film 185 may be formed on the pad isolation films 180 and on parts of the landing pads LP, exposed by the pad isolation films 180.

Thereafter, lower electrodes 191 may be formed on the parts of the landing pads LP, exposed by the pad isolation films 180. Thereafter, a capacitor dielectric film 182 and an upper electrode 193 may be sequentially formed on the lower electrodes 191. Accordingly, a method of fabricating a semiconductor memory device with improved operating properties can be provided.

Meanwhile, in a case where the sacrificial spacers 150S and the sacrificial fence liner 170S include silicon oxide, the removal of the sacrificial spacers 150A and the sacrificial fence liner 170S, described above with reference to FIG. 20, may not be performed. That is, referring again to FIGS. 6 and 7, the pad isolation films 180, which fill the fourth trenches t4, may be formed after the processes described above with reference to FIGS. 9 through 19. The pad isolation films 180 may be formed on the sacrificial fence liner 170S. Thereafter, the etching stopper film 185 and capacitors 190 may be formed. In this manner, fourth spacers 154, which include silicon oxide, and second fence liners 173, which include silicon oxide, may be formed.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

What is claimed is:

1. A semiconductor memory device comprising:
a substrate extending in a first direction and second direction perpendicular to the first direction;
bitline structures arranged on the substrate in the first direction, the bitline structures extending in the second direction;
spacer structures disposed on sidewalls of the bitline structures to extend in the second direction, the spacer structures including spacers, which are formed of air or silicon oxide;
contact structures disposed between the spacer structures and arranged in the second direction;
fence structures filling gaps between the contact structures and between the spacer structures; and
pad isolation films isolating the contact structures on the bitline structures, the spacer structures, and the fence structures,
wherein
the fence structures include first fence liners and second fence liners, which are on the first fence liners and are formed of one of air and silicon oxide, and
the second fence liners overlap with the spacers in the first direction.

2. The semiconductor memory device of claim 1, wherein the second fence liners are disposed between spacers that are adjacent to one another in the first direction.

3. The semiconductor memory device of claim 1, wherein top surfaces of the second fence liners are defined by the pad isolation films.

4. The semiconductor memory device of claim 1, wherein a width, in the first direction, of the spacer structures is uniform.

5. The semiconductor memory device of claim 1, wherein the first fence liners extend along sidewalls of the contact structures and sidewalls of the spacer structures.

6. The semiconductor memory device of claim 1, wherein the second fence liners are connected to the spacers.

7. The semiconductor memory device of claim 6, wherein the second fence liners and the spacers are formed of silicon oxide.

8. The semiconductor memory device of claim 6, further comprising:
gate structures buried in the substrate, the gate structures extending in the first direction,
wherein the second fence liners cover the bitline structures and the spacer structures on the gate structure.

9. The semiconductor memory device of claim 6, wherein
the contact structures include buried contacts, which are connected to the substrate, and landing pads, which are on the buried contacts, and
the buried contacts are disposed in spaces defined by the second fence liners and the spacers.

10. A semiconductor memory device comprising:
a substrate extending in a first direction and second direction perpendicular to the first direction;
bitline structures arranged on the substrate in the first direction, the bitline structures extending in the second direction;
spacer structures disposed on sidewalls of the bitline structures;
contact structures disposed between the spacer structures and arranged in the second direction;
fence structures filling gaps between the contact structures and between the spacer structures; and
pad isolation films isolating the contact structures on the bitline structures, the spacer structures, and the fence structures,
wherein
the fence structures include first fence liners, which extend along sidewalls of the spacer structures and sidewalls of the contact structures, and second fence liners, which are on the first fence liners, are formed of air, and fill gaps between the contact structures and gaps between the spacer structures, and
top surfaces of the second fence liners are defined by the pad isolation films.

11. The semiconductor memory device of claim 10, wherein in a cross-sectional view, taken along the first direction, of the fence structures, a width of the spacer structures is uniform.

12. The semiconductor memory device of claim 10, wherein
the spacer structures include air spacers, and
in a cross-sectional view, taken along the first direction, of the fence structures, top surfaces of the air spacers are defined by the pad isolation films.

13. The semiconductor memory device of claim 12, wherein top surfaces of the air spacers are convex toward the pad isolation films.

14. The semiconductor memory device of claim 10, wherein top surfaces of the second fence liners are convex toward the pad isolation films.

15. The semiconductor memory device of claim 10, wherein
the spacer structures include air spacers, and
in a cross-sectional view, taken along the first direction, of the contact structures, top surfaces of the air spacers are positioned below bottom surfaces of the pad isolation films.

16. The semiconductor memory device of claim 15, wherein
the spacer structures include first spacers and second spacers, and
the air spacers are interposed between the first spacers and the second spacers.

17. The semiconductor memory device of claim 16, wherein in a cross-sectional view, taken along the first direction, of the fence structures, the top surfaces of the air spacers are defined by the pad isolation films.

18. The semiconductor memory device of claim 10, wherein the contact structures include buried contacts, which are connected to the substrate, between the bitline structures, landing pads, which are on the buried contacts, and barrier films, which are disposed between the buried contacts and the landing pads and extend along top surfaces of the buried contacts, the sidewalls of the spacer structures, and top surfaces of the bitline structures.

19. A semiconductor memory device comprising:
a substrate extending in a first direction and second direction perpendicular to the first direction;
gate structures including gate electrodes, which extend in the first direction in the substrate, and gate capping films, which extend in the first direction in the substrate;
bitline structures extending in the second direction, which intersects the first direction, on the substrate, the bitline structures being arranged in the second direction;
spacer structures disposed on sidewalls of the bitline structures to extend in the second direction, the spacer structures including air spacers;
contact structures including buried contacts, which are connected to the substrate, between the spacer structures, and are arranged in the second direction, landing pads, which are on the buried contacts, and barrier films, which are disposed between the buried contacts and the landing pads and extend along top surfaces of the buried contacts, sidewalls of the spacer structures, and top surfaces of the bitline structures;
fence structures having bottom surfaces defined by the gate capping films, the fence structures filling trenches, which have sidewalls defined by the contact structures and the spacer structures; and
pad isolation films isolating the contact structures on the bitline structures, the spacer structures, and the fence structures,
wherein
top surfaces of the air spacers are defined by the pad isolation films, on the gate structures,
the fence structures include first fence liners, which are formed along sidewalls and bottoms of the trenches, and second fence liners, which are formed of air and are defined by the first fence liners and the pad isolation films, and
the second fence liners overlap with the spacers in the first direction.

20. The semiconductor memory device of claim 19, wherein a width of the spacer structures is uniform on the gate electrodes.
